(19) United States
(12) Patent Application Publication
(10) Pub. No.: US 2010/0074035 A1
(43) Pub. Date: Mar. 25, 2010

(54) SEMICONDUCTOR MEMORY DEVICE

(76) Inventor: Chang-Ho DO, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 12/630,765

(22) Filed: Dec. 3, 2009

Related U.S. Application Data
(63) Continuation of application No. 11/479,348, filed on Jun. 29, 2006.

(30) Foreign Application Priority Data
Sep. 29, 2005 (KR) 2005-0090964
Apr. 7, 2006 (KR) 2006-0031956

(51) Int. Cl. G11C 7/22; G11C 7/00

(52) U.S. Cl. 365/189.14; 365/193; 365/191

(57) ABSTRACT

A semiconductor memory device and method to perform a read operation and a write operation effectively. The semiconductor memory device and method includes: performing a first operation for inputting and outputting data in response to a first clock signal having a first frequency; and performing a second operation for storing and reading out the data in a core block in response to a second clock signal having a second frequency, wherein the first frequency is different from the second frequency.

### FIELD OF THE INVENTION

The present invention relates to a semiconductor memory device, and more particularly to a semiconductor memory device using a plurality of clock signals.

### DESCRIPTION OF RELATED ARTS

Generally, a semiconductor memory device has a row operation and a column operation. In the row operation, the semiconductor memory device receives a row address and a row command, and selects a word line corresponding to the row address of a plurality of word lines in a core area. In the column operation, the semiconductor memory device receives a column address and a column command, and selects one or more bit lines corresponding to the column address of a plurality of bit lines in the core area. An accessed data is determined by the selected word line and bit line. In the column operation, the semiconductor memory device outputs the accessed data external to the device. Typically, the column operation includes a write operation and a read operation.

Recently, the semiconductor memory device performs the row and the column operations in synchronization with a clock signal, i.e., a system clock signal provided from a clock generator of a system. Especially, the semiconductor memory device outputs one or more data in synchronization with the clock signal. However, the semiconductor memory device does not have a sufficient timing margin for outputting the accessed data from the core area to an external destination during the column operation since the accessed data can be one bit or more.

To overcome the problem, the semiconductor memory device performs a data prefetch operation. The data prefetch operation is that the semiconductor memory device transfers the accessed data into a data output circuit before the accessed data is outputted to an external destination. Then, when the accessed data is outputted, the semiconductor memory device outputs the accessed data in synchronization with the clock signal. Typically, the data prefetch operation is performed in synchronization with transition of the clock signal. The speed of the data prefetch operation is decided by a frequency of the clock signal. Therefore, if the frequency of the clock signal becomes higher, the speed of the prefetch operation can become faster.

As described above, a cycle of the column operation of the semiconductor memory device does not correspond to a period of the clock signal. The cycle of the column operation corresponds to two periods, four periods or eight periods of the clock signal. For example, in case of the semiconductor memory device according to double data rate synchronization random access memory (DDR-SRAM) specification, the column operation is performed during two periods of the clock signal and 2 bit data are prefetched by the prefetch operation. In case of DDR2-SRAM or DDR3-SRAM specification, the column operation is performed during four periods and eight periods of the clock signal and 4 bit data and 8 bit data are prefetched by the prefetch operation, respectively.

In reference, an interval period between a column operation and next column operation is called ‘tCCD’ in DDR-SRAM, DDR2-SRAM and DD3-SRAM specifications. Therefore, the ‘tCCD’ is a minimum interval that the semiconductor memory device receives a column command and a column address after receiving a previous column command and a previous column address and performs the column operation.

### SUMMARY OF THE INVENTION

In accordance with an embodiment of the present invention, there is provided a semiconductor memory device, including: performing a first operation for inputting and outputting data in response to a first clock signal having a first frequency; and performing a second operation for storing and reading out the data in a core block in response to a second clock signal having a second frequency, wherein the first frequency is different from the second frequency.

In accordance with another embodiment of the present invention, there is provided a semiconductor memory device, including: an operating unit for storing first data for a write operation or reading out second data for a read operation in response to a first clock signal having a first frequency; and a data input/output unit for inputting the first data from an external source or outputting the second data to an external destination in response to a second clock signal having a second frequency, wherein the first frequency is different from the second frequency.

In accordance with another embodiment of the present invention, there is provided a semiconductor memory device, including: an operating clock generating unit for generating an operating clock in response to a first external clock having a first frequency; a data clock generating unit for generating a data clock in response to a second external clock having a second frequency; an operating unit for storing first data for a write operation or reading out second data for a read operation in response to the operating clock; and a data input/output unit for receiving the first data from an external source or outputting the second data to an external destination in response to the data clock, wherein the first frequency is different from the second frequency.

In accordance with another embodiment of the present invention, there is provided a method for operating a semiconductor memory device, including: receiving a write command and addresses in response to an operating clock having a first frequency; receiving data from an external source in response to a data clock having a second frequency; and storing the data into cells corresponding to the write command and the addresses in response to the operating clock.

In accordance with another embodiment of the present invention, there is provided a method for operating a semiconductor memory device, including: receiving a read command and addresses in response to an operating clock having a first frequency; reading out data of cells corresponding to the read command and the addresses in response to the operating clock; and outputting the data to an external destination in response to a data clock having a second frequency.

In accordance with another embodiment of the present invention, there is provided a semiconductor memory device, including: a data strobe signal generating unit for generating an internal data strobe signal in response to a data strobe signal for a write operation and generating a read data strobe signal for a read operation in response to a data clock; an operating unit for storing first data for the write operation or reading out a second data for the read operation in response to an operating clock; and a data input/output unit for receiving the first data from an external source in response to the internal data strobe signal and outputting the second data to an external destination in response to the data clock.

In accordance with another embodiment of the present invention, there is provided a semiconductor memory device, including: an operating clock generating unit for generating an operating clock in response to a first external clock having a first frequency; a data clock generating unit for generating a data clock in response to a second external clock having a second frequency; a data strobe signal generating unit for generating an internal data strobe signal in response to a data strobe signal for a write operation and generating a data strobe signal for a read operation in response to the data clock; an operating unit for storing first data for a write operation or reading out second data for a read operation in response to the operating clock; and a data input/output unit for receiving the first data from an external source in response to the internal data strobe signal and outputting the second data to an external destination in response to the data clock, wherein the first frequency is different from the second frequency.

In accordance with another embodiment of the present invention, there is provided a method for operating a semiconductor memory device, including: receiving a read command and addresses in response to an operating clock having a first frequency; reading out data stored in cells corresponding to the read command and the addresses in response to the operating clock; generating a data strobe signal by using a data clock having a second frequency; and outputting the data to an external destination in response to the data strobe signal, wherein the first frequency is different from the second frequency.

### BRIEF DESCRIPTION OF THE DRAWINGS

The above and other objects and features of the present invention will become apparent from the following description of preferred embodiments taken in conjunction with the accompanying drawings, in which:

FIG. 1 shows a block diagram of a semiconductor memory device according to a first embodiment of the present invention;

FIG. 2A shows a timing diagram for a write operation of the semiconductor memory device in FIG. 1;

FIG. 2B shows a timing diagram for a read operation of the semiconductor memory device in FIG. 1;

FIG. 3 shows a block diagram of a semiconductor memory device according to a second embodiment of the present invention;

FIG. 4A shows a timing diagram for a write operation of the semiconductor memory device in FIG. 3;

FIG. 4B shows a timing diagram for a read operation of the semiconductor memory device in FIG. 3;

FIG. 5 shows a block diagram of a semiconductor memory device according to a third embodiment of the present invention;

FIG. 6A shows a timing diagram for a write operation of the semiconductor memory device in FIG. 5; and

FIG. 6B shows a timing diagram for a read operation of the semiconductor memory device in FIG. 5.

### DETAILED DESCRIPTION OF THE INVENTION

Hereinafter, a semiconductor memory device in accordance with the present invention will be described in detail referring to the accompanying drawings.

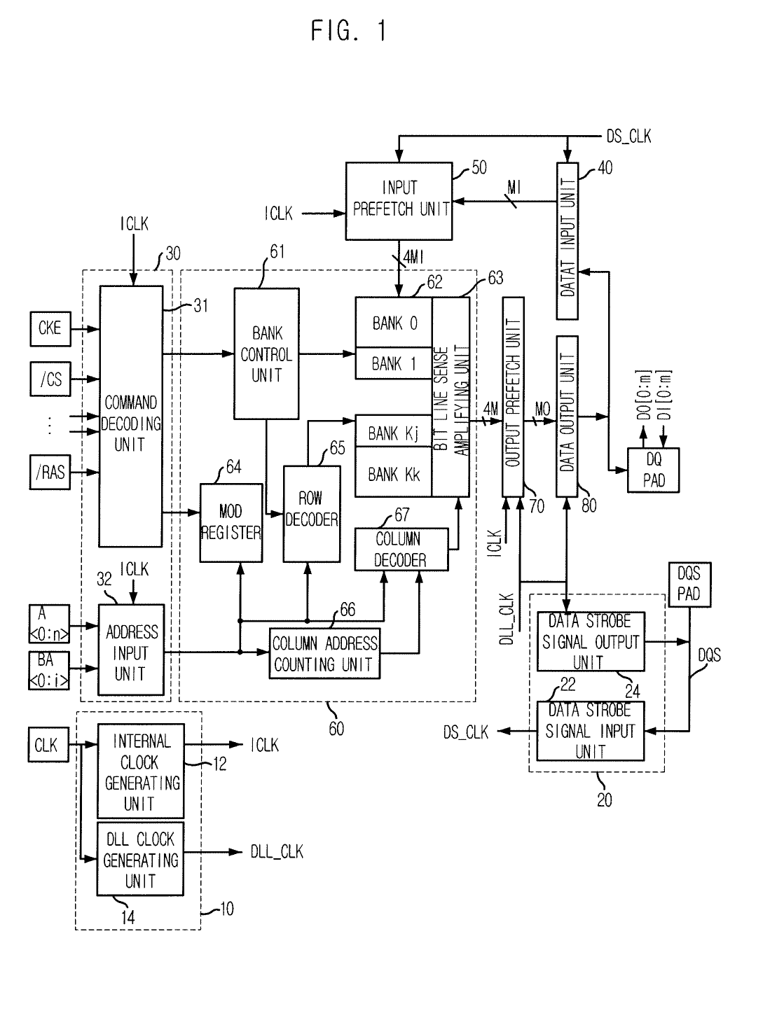

FIG. 1 shows a block diagram of a semiconductor memory device according to a first embodiment of the present invention. The semiconductor memory device includes a clock generating unit 10, a data strobe signal generating unit 20, a access signal input unit 30, a data input circuit 40, an input prefetch unit 50, a core block 60, a output prefetch unit 70 and a data output unit 80.

The clock generating unit 10 receives an external clock CLK and generates an internal clock ICLK and a DLL clock DLL_CLK. The clock generating unit 10 includes an internal clock buffer unit 12 and a DLL clock generating unit 14. The internal clock buffer unit 12 receives the external clock CLK to output the internal clock ICLK. The DLL clock generating unit 14 receives the external clock CLK to generate the DLL clock DLL_CLK. The DLL clock DLL_CLK is a clock delayed for a programmed time to adjust a difference time between an output timing of data and the transition edge of the external clock CLK.

The data strobe signal generating unit 20 includes a data strobe signal input unit 22 and a data strobe signal output unit 24. The data strobe signal input unit 22 receives a data strobe signal DQS provided from an external source to generate an internal data strobe signal DS_CLK having a level of an internal operating voltage. The data strobe signal output unit 24 outputs the DLL clock DLL_CLK as the data strobe signal DQS.

The access signal input unit 30 includes a command decoding unit 31 and an address input unit 32. The command decoding unit 31 receives and decodes command signals, e.g., /CS, /RAS and CKE in response to the internal clock ICLK and generate internal command signals into the core block 60. The address input unit 32 receives and decodes an address A<0:n> and a bank address BA<0:i> inputted from an external source to generate an internal address and an internal bank address into the core block 60.

The data input unit 40 receives a data DI[0:m] through the input/output pad DQ PAD inputted from an external source in response to the internal data strobe signal DS_CLK to output an internal data MI.

The input prefetch unit 50 prefetches the internal data MI and aligns the internal data MI into a data 4MI in parallel in response to the internal data strobe signal DS_CLK, and outputs the data 4MI in response to the internal clock ICLK into the core block 60. The input prefetch unit 50 can align the internal data MI into the data 4MI in parallel in response to the internal clock ICLK.

The core block 60 includes a bank control unit 61, a plurality of banks 62, a bit line sense amplifying unit 63, a mode register 64, a row decoder 65, a column address counter and a column decoder 67. The core block 60 inputs or outputs data corresponding to the internal address and the internal bank address in response to the internal command signals from the input prefetch unit 50 or into the output prefetch unit 70.

The output prefetch unit 70 prefetches the data from the core block 70 in response to the internal clock ICLK; aligns the prefetched data into a series data in response to the internal clock ICLK; outputs the series data into the data output unit 80 in response to the DLL clock DLL_CLK. The output prefetch unit 70 aligns the prefetched data into a series data in response to the DLL clock DLL_CLK. The data output unit 80 outputs the series data as an output data DO[0:m] through the input/output pad DQ PAD in response to the DLL clock DLL_CLK.

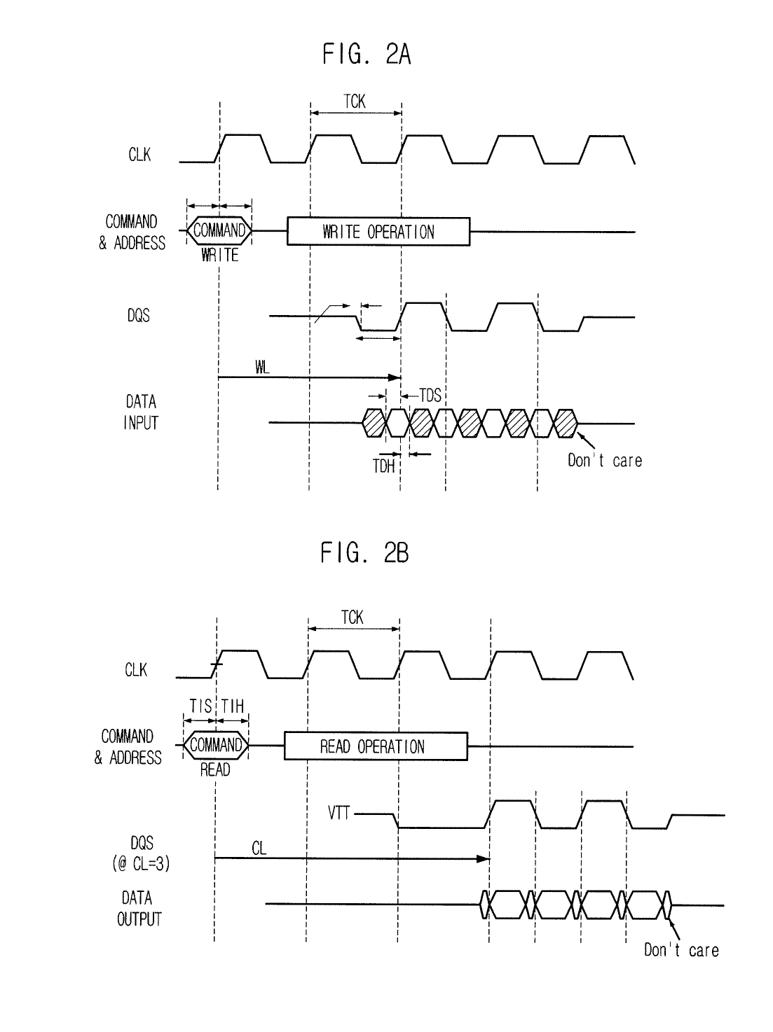

FIG. 2A shows a timing diagram for a write operation of the semiconductor memory device in FIG. 1.

In case of the writing operation, at first, the internal clock generating unit 12 generates the internal clock ICLK using the external clock CLK. A frequency of the internal clock ICLK is the same as that of the external clock CLK. The command decoding unit 31 receives the command signals, e.g., /CS and /RAS and CKE, and generates the internal command signal, i.e., an internal write command for the write operation. The address input unit 32 generates the internal address and the internal bank address into the core block 60 using an address A<0:n> and a bank address BA<0:i> inputted from an external source.

Input Data DI[0:m] is inputted through the input/output pad DQ PAD to the data input unit 40 in response to the transition of the data strobe signal DQS. The data strobe signal input unit 22 generates the internal data strobe signal DS_CLK using the data strobe signal DQS. The internal data strobe signal DS_CLK has a transition in response to a rising edge and falling edge of the data strobe signal DQS.

The data input unit 40 transfers the input data DI[0:m] as the internal data MI to the input prefetch unit 50 in response to transition of the internal data strobe signal DS_CLK. The input prefetch unit 50 aligns the internal data MI into the data 4MI in parallel in response to the internal data strobe signal DS_CLK and outputs the data 4MI in response to the internal clock ICLK. The core block 60 writes the data 4MI into cells corresponding to the internal address.

In reference, a write latency WL in FIG. 2A is a time period between an input time of a command for a write operation and an input time of a data for the write operation into the data input/output pad DQ PAD. Typically, the write latency WL is specified as ‘WL=AL+CL−1’. Commonly, Additive Latency is abbreviated to “AL” and CAS Latency is abbreviated to “CL” in the DDR2 or the DDR3 specifications.

As described above, the semiconductor memory device uses the internal data strobe signal DS_CLK derived from the data strobe signal DQS as a reference signal when data are inputted and are aligned into a parallel data. Alternative, the semiconductor memory device uses the internal clock ICLK derived from the external clock CLK as a reference signal when command signals and addresses are inputted and a write operation is performed. The internal data strobe signal DS_CLK and the internal clock ICLK have the same frequency.

FIG. 2B shows a timing diagram for a read operation of the semiconductor memory device in FIG. 1.

In case of the reading operation, the internal clock generating unit 12 generates the internal clock ICLK using the external clock CLK. The DLL clock generating unit 14 generates the DLL clock DLL_CLK. The DLL clock DLL_CLK is a clock delayed for the programmed time, as described above. A frequency of the internal clock ICLK and the DLL clock DLL_CLK is the same as that of the external clock CLK.

The command decoding unit 31 receives the command signals, e.g., /CS and /RAS and CKE, and generates the internal command signal, i.e., an internal read command for the read operation. The address input unit 32 generates the internal address and the internal bank address into the core block 60 using the address A<0:n> and the bank address BA<0:i> inputted from an external source.

The core block 60 outputs data 4M corresponding to the address A<0:n> and the bank address BA<0:i> into the output prefetch unit 70.

The output prefetch unit 70 receives the data 4M in parallel in response to the internal clock ICLK and aligns the data 4M into data MO in series in response to the DLL clock DLL_CLK. The data output unit 80 outputs the data MO as the output data DO[0:m] through the input/output pad DQ PAD in response to the DLL clock DLL_CLK. The data strobe signal output unit 24 generates the data strobe signal DQS using the DLL clock DLL_CLK through a data strobe signal pad DOQ PAD. The output timing of the output data DO[0:m] is synchronized with the transition of the data strobe signal DQS.

In reference, a read latency RL is a time period between an input time of a command for a read operation and an output time of a data for the read operation into the data input/output pad DQ PAD. Typically, the read latency RL is specified as ‘RL=AL+CL’ in the DDR2 and the DDR3 specification. In FIG. 2B, the semiconductor memory device is set as AL=0 and CL=3. Then, the CAS latency CL is equal to the read latency RL.

As described above, the semiconductor memory device uses the DLL clock DLL_CLK when outputs the output data and outputs the DLL clock DLL_CLK as the data strobe signal DQS. Alternatively, the semiconductor memory device uses the internal clock ICLK derived from the external clock CLK as a reference signal when command signals and addresses are inputted and a read operation is performed. Also, the DLL clock DLL_CLK and the internal clock ICLK have the same frequency.

In summary, the semiconductor memory device performs the write operation or the read operation using reference signals having the same frequency, i.e., the DLL clock DLL_CLK, the internal clock ICLK and the internal data strobe signal DS_CLK.

On the other hand, typically, the semiconductor memory device performs the write operation or the read operation for more than a period. That is, when the semiconductor memory device performs the write operation or the read operation, two or more cycles of the reference signals are needed. Whenever the reference signals has a transition, the semiconductor memory device consumes a lot of power. By the way, a prior art semiconductor memory device does not perform meaningful operations every transition of the reference signals. Therefore, the prior art semiconductor memory device wastes needless power at any transition of the reference signals.

In order to raise a data transmission rate, the frequency of the reference signals must be raised. As the frequency of the reference signals becomes higher, the needless power becomes higher. Because the transition of the reference signals that the semiconductor memory device does not perform any meaningful operation, the consumed power becomes higher.

To solve the above problem, semiconductor memory devices according to the next embodiment of the present invention use two reference signals having different frequencies, respectively.

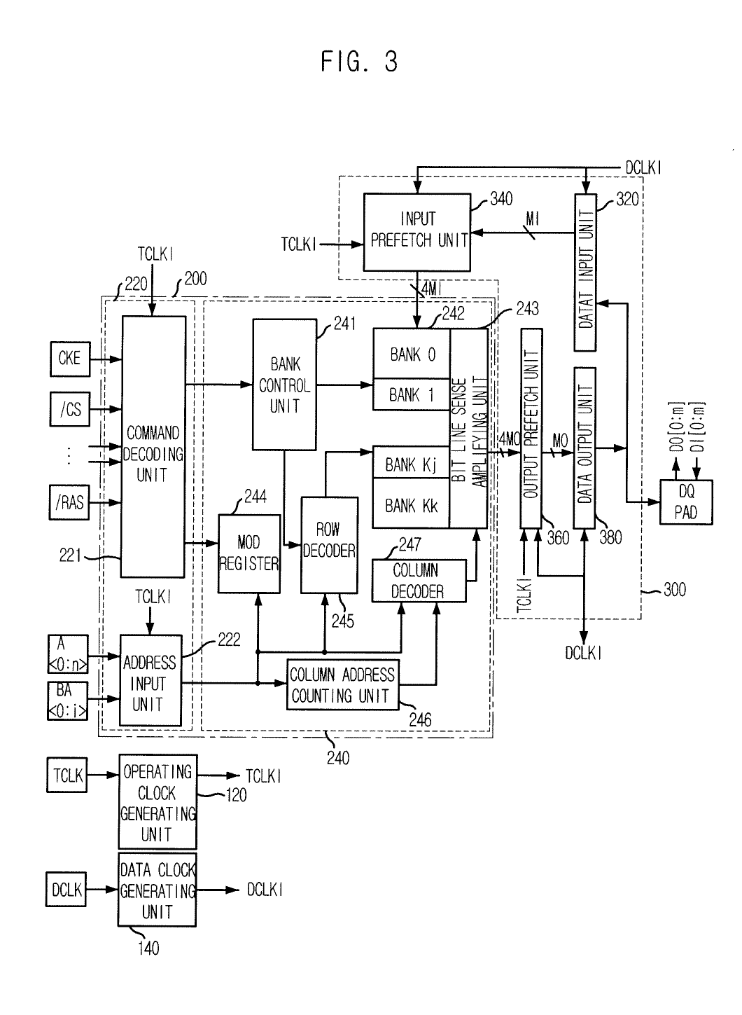

FIG. 3 shows a block diagram of a semiconductor memory device according to a second embodiment of the present invention.

The semiconductor memory device includes an operating clock generating unit 120, a data clock generating unit 140, an operating block 200 and a data input/output circuit 300.

The operating clock generating unit 120 receives the first external clock TCLK and generates an internal operating clock TCLKI. A frequency of the internal operating clock TCLKI is the same as that of the first external clock TCLK. The data clock generating unit 140 receives the second external clock DCLK and generates a data clock DCLKI. A frequency of the data clock DCLK is the same as that of the second external clock DCLKI. However, the frequency of the second external clock DCLK is higher than that of the first external clock TCLK.

The operating block 200 performs an operation in response to the operating clock TCLKI. Especially, the operating block 200 outputs data for the read operation into the data input/output circuit 300 and receives data for the write operation from the data input/output circuit 300 in response to the operating clock TCLKI, respectively. The operating block 200 includes an access signal input unit 220 and a core block 240. The access signal input unit 220 includes a command decoding unit 221 and an address input unit 222. The command decoding unit 221 receives and decodes command signals, e.g., /CS, /RAS and CKE in response to the operating clock TCLKI and generates internal command signals into the core block 240. The address input unit 222 receives and decodes an address A<0:n> and a bank address BA<0:i> inputted from an external source to generate an internal address and an internal bank address into the core block 240. The core block 240 includes a bank control unit 241, a plurality of banks 242, a bit line sense amplifying unit 243, a mode register 244, a row decoder 245, a column address counter 246 and a column decoder 247. The core block 240 inputs or outputs data corresponding to the internal address and the internal bank address in response to the internal command signals from or into the data input/output circuit 300, respectively.

The data input/output circuit 300 includes a data input unit 320, a data input prefetch unit 340, a data output prefetch unit 360 and a data output unit 380. The data input unit 320 receives a data DI[0:m] through an input/output pad DQ PAD inputted from an external source in response to the data clock DCLKI to output an internal data MI. The input prefetch unit 340 prefetches the internal data MI and aligns the internal data MI into a data 4MI in parallel in response to the data clock DCLKI, and outputs the data 4MI in response to the operating clock TCLKI into the core block 240. The input prefetch unit 340 can align the internal data MI into a data 4MI in parallel in response to the operating clock TCLKI. The output prefetch unit 360 prefetches the data from the core block 240 in response to the operating clock TCLKI; aligns the prefetched data into a series data in response to the operating clock TCLKI; outputs the series data into the data output unit 380 in response to the data clock DCLKI. The output prefetch unit 360 can align the prefetched data into the series data in response to the data clock DCLKI. The data output unit 380 outputs the series data as an output data DO[0:m] through the input/output pad DQ PAD in response to the data clock DCLKI. The input prefetch unit 340 and the output prefetch unit 360 change a reference signal to transfer and handle the data. That is, the input prefetch unit 340 changes the data clock DCLKI into the operating clock TCLKI as a reference signal to handle the data. The output prefetch unit 360 changes the operating clock TCLKI into the data clock DCLKI as a reference signal to transfer the data. That is called a domain cross operation.

In summary, the semiconductor memory device according to the second embodiment receives two reference signals, i.e., the first external clock TCLK and the second external clock DCLK having different frequencies from each other. The first external clock TCLK is applied to an input of command signals and addresses and for a core block having a plurality of cells. The second external clock DCLK is applied to an input and an output data.

In addition, the semiconductor memory device can receive one reference signal and divides the one reference to two or more internal reference signals and then, applies the divided signals to appropriate operations for data access. In this case, the semiconductor memory device may have a dividing unit for dividing a frequency of a signal.

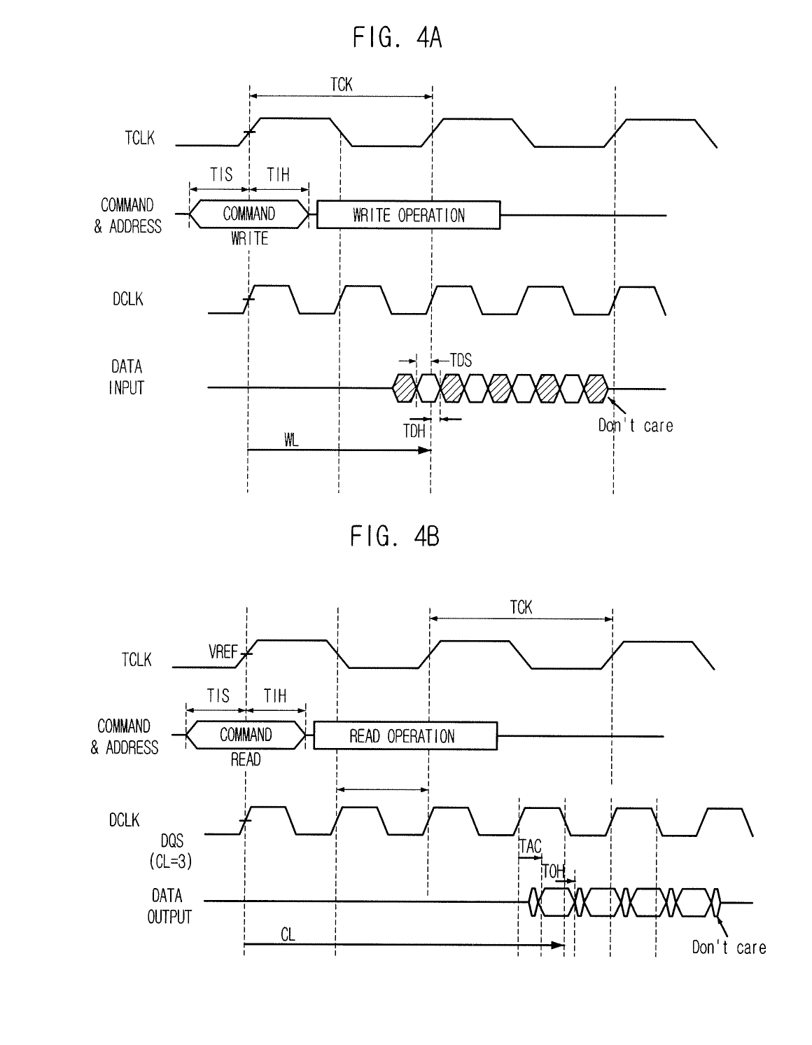

FIG. 4A shows a timing diagram for a write operation of the semiconductor memory device in FIG. 3.

In case of the writing operation, at first, the operating clock generating unit 120 generates the operating clock TCLKI using the first external clock TCLK. A frequency of the operating clock TCLK is the same as that of the first external clock TCLK. The data clock generating unit 140 generates the data clock DCLKI using the second external clock DCLK. A frequency of the data clock DCLK is the same as that of the second external clock DCLK. The frequency of the second external clock DCLK is higher than that of the first external clock TCLK. In this exemplification, the frequency of the second external clock DCLK is two times as high as that of the first external clock TCLK. Therefore, the frequency of the data clock DCLKI is two times as high as that of the first external clock TCLKI.

The command decoding unit 221 receives the command signals, e.g., /CS and /RAS and CKE, and generates the internal write command for the write operation. The address input unit 222 generates the internal address and the internal bank address into the core block 240 using an address A<0:n> and a bank address BA<0:i> inputted from an external source.

Input Data DI[0:m] is inputted through the input/output pad DQ PAD to the data input unit 320 in response to the transition of the second external clock DCLK. The data input unit 320 transfers the input data DI[0:m] as the internal data MI to the input prefetch unit 340 in response to transition of the data clock DCLKI. The input prefetch unit 340 aligns the internal data MI into the data 4MI in parallel in response to the data clock DCLKI and outputs the data 4MI in response to the operating clock TCLKI. The core block 240 writes the data 4MI into cells corresponding to the internal address.

As described above, the semiconductor memory device uses the data clock DCLKI derived from the second external clock DCLK as a reference signal when data are inputted and are aligned into a parallel data. Alternatively, the semiconductor memory device uses the operating clock TCLKI derived from the first external clock TCLK as a reference signal when command signals and addresses are inputted and a write operation is performed.

FIG. 4B shows a timing diagram for a read operation of the semiconductor memory device in FIG. 3.

In case of the reading operation, the operating clock generating unit 120 generates the operating clock TCLKI using the first external clock TCLK. A frequency of the operating clock TCLK is the same as that of the first external clock TCLK. The data clock generating unit 140 generates the data clock DCLKI using the second external clock DCLK. A frequency of the data clock DCLK is the same as that of the second external clock DCLK. The frequency of the second external clock DCLK is higher than that of the first external clock TCLK. In this exemplification, the frequency of the second external clock DCLK is two times as high as that of the first external clock TCLK. Therefore, the frequency of the data clock DCLKI is two times as high as that of the first external clock TCLKI.

The command decoding unit 221 receives the command signals, e.g., /CS and /RAS and CKE, and generates the internal read command for the read operation. The address input unit 222 generates the internal address and the internal bank address into the core block 240 using an address A<0:n> and a bank address BA<0:i> inputted from an external source.

The core block 240 outputs data 4MO corresponding to the address A<0:n> and the bank address BA<0:i> into the output prefetch unit 360.

The output prefetch unit 360 receives the data 4MO in parallel in response to the operating clock TCLK and aligns the data 4MO into data MO in series in response to the data clock DCLKI. The data output unit 380 outputs the data MO as the output data DO[0:m] through the input/output pad DQ PAD in response to the data clock DCLKI.

A correlation between the frequencies of the first external clock TCLK and the second external clock DLCK is determined as the bit number for prefetching data. For example, as described above, in case of 4 bit prefetch operation, the frequency of the second external clock DCLK can be two times as high as that of the first external clock TLCK. Also, in case of 8 bit prefetch operation, the frequency of the second external clock DCLK can be four times as high as that of the first external clock TLCK.

As described above, the semiconductor memory device uses the data clock DCLKI derived from the second external clock TCLK when outputting the output data. The semiconductor memory device uses the operating clock TCLK derived from the first external clock TCLK as a reference signal when command signals and addresses are inputted and a read operation is performed.

In summary, the semiconductor memory device performs the write operation or the read operation using two reference signals having the different frequency each other, i.e., the data clock DCLKI and the operating clock TCLKI.

If the frequency of the second external clock DLCK is raised at state of fixing the frequency of the first external clock TLCK, data transmission rate of the semiconductor memory device is raised and the needless power consumption is reduced at the same time. That is, the rate of data input/output is determined to be the frequency of the second external clock DLCK and the operation for accessing data is effectively the frequency of the first external clock TCLK having a relatively lower frequency. Therefore, in core area, needless power consumption from the transition of the operating clock can be reduced.

Besides, because the semiconductor memory device performs a read operation or a write operation in response to the first external clock TCLK having a relatively lower frequency, a margin of set-up time and hold time for transferring data in the semiconductor memory device can be increased.

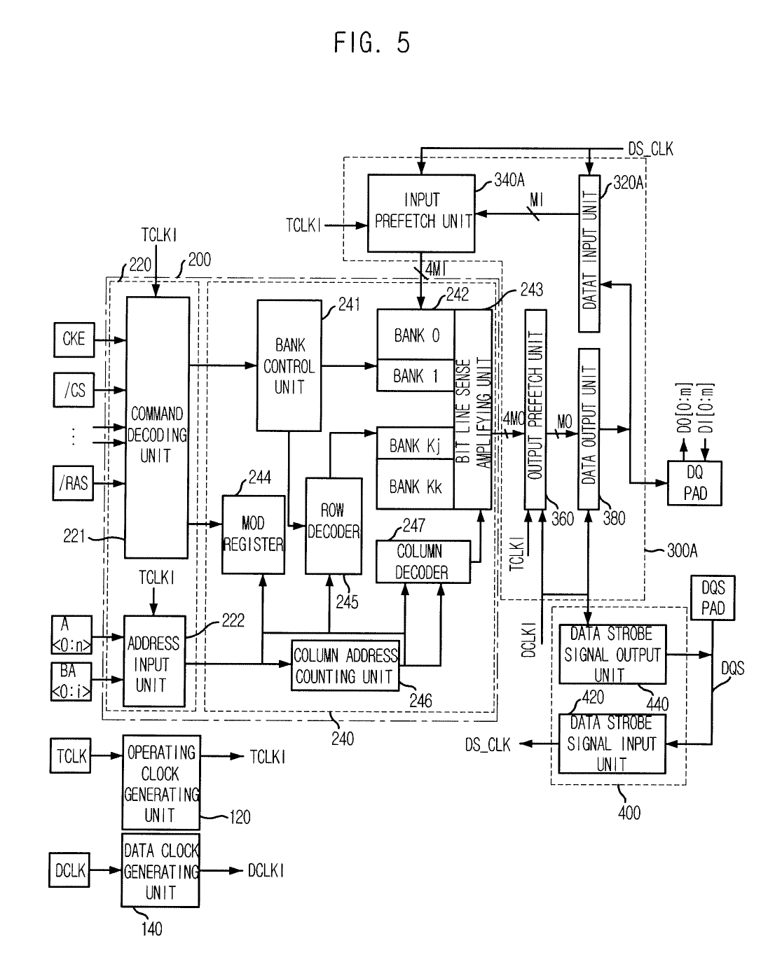

FIG. 5 shows a block diagram of a semiconductor memory device according to a third embodiment of the present invention.

The semiconductor memory device includes an operating clock generating unit 120, a data clock generating unit 140, an operating block 200, a data input/output circuit 300A and a data strobe signal generating unit 400.

The operating clock generating unit 120 receives the first external clock TCLK and generates an internal operating clock TCLKI. A frequency of the internal operating clock TCLKI is the same as that of the first external clock TCLK. The data clock generating unit 140 receives the second external clock DCLK and generates a data clock DCLKI. A frequency of the data clock DCLK is the same as that of the second external clock DCLKI. However, the frequency of the second external clock DCLK is higher than that of the first external clock TCLK.

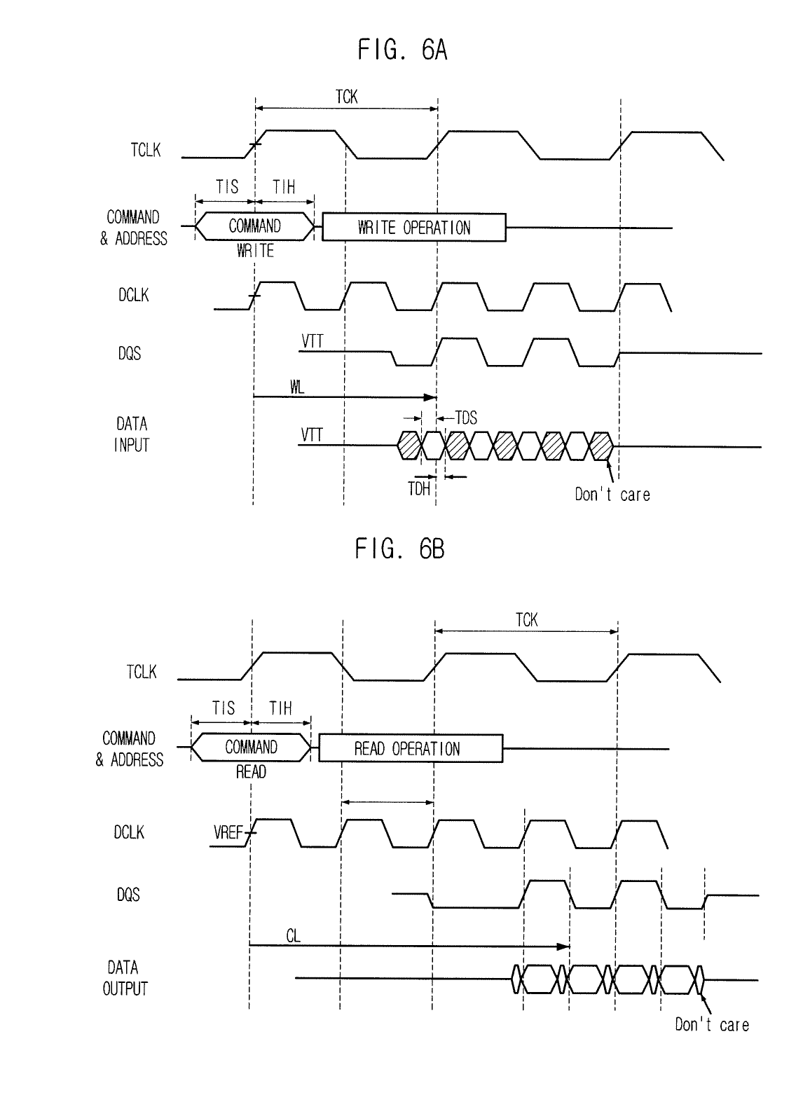

The data strobe signal generating unit 400 includes a data strobe signal input unit 420 and a data strobe signal output unit 440. The data strobe signal input unit 420 receives a data strobe signal DQS provided from an external source to generate an internal data strobe signal DS_CLK. The data strobe signal output unit 440 outputs the data clock DLL_CLK as the data strobe signal DQS. The semiconductor memory device in FIG. 6 uses the data strobe signal DQS for inputting or outputting data. A frequency of the data strobe signal DQS is the same as that of the second external clock DCLK.

The operating block 200 performs an operation in response to the operating clock TCLKI. Especially, the operating block 200 outputs data for the read operation into the data input/output circuit 300A and receives data for the write operation from the data input/output circuit 300A in response to the operating clock TCLKI, respectively. The operating block 200 includes an access signal input unit 220 and a core block 240. The access signal input unit 220 includes a command decoding unit 221 and an address input unit 222. The command decoding unit 221 receives and decodes command signals, e.g., /CS, /RAS and CKE in response to the operating clock TCLKI and generate internal command signals into the core block 240. The address input unit 222 receives and decodes an address A<0:n> and a bank address BA<0:i> inputted from an external source to generate an internal address and an internal bank address into the core block 240. The core block 240 includes a bank control unit 241, a plurality of banks 242, a bit line sense amplifying unit 243, a mode register 244, a row decoder 245, a column address counter 246 and a column decoder 247. The core block 240 inputs or outputs data corresponding to the internal address and the internal bank address in response to the internal command signals from or into the data input/output circuit 300, respectively.

The data input/output circuit 300A includes a data input unit 320A, a data input prefetch unit 340A, a data output prefetch unit 360 and a data output unit 380. The data input unit 320A receives a data DI[0:m] through an input/output pad DQ PAD inputted from an external source in response to the internal data strobe signal DS_CLK to output an internal data MI. The input prefetch unit 340A prefetches the internal data MI and aligns the internal data MI into a data 4MI in parallel in response to the internal data strobe signal DS_CLK, and outputs the data 4MI in response to the operating clock TCLKI into the core block 240. The input prefetch unit 340A aligns the internal data MI into a data 4MI in parallel in response to the operating clock TCLKI. The output prefetch unit 360 prefetches the data from the core block 240 in response to the operating clock TCLKI; aligns the prefetched data into a series data in response to the operating clock TCLKI; outputs the series data into the data output unit 380 in response to the data clock DCLKI. The output prefetch unit 360 aligns the prefetched data into the series data in response to the data clock DCLKI. The data output unit 380 outputs the series data as an output data DO[0:m] through the input/output pad DQ PAD in response to the data clock DCLKI.

In summary, the semiconductor memory device according to the third embodiment receives three reference signals, i.e., the first external clock TCLK, the second external clock DCLK and the data strobe signal DQS having different frequencies from one another. In this exemplification, it is described that the second external clock DCLK and the data strobe signal DQS are the same frequency. The first external clock TCLK is applied to an input of command signals and addresses and for a core block having a plurality of cells. The second external clock DCLK is applied to an output operating of data. The third external clock DQS is applied to input data.

In addition, the semiconductor memory device can receive only one reference signal and divides the one reference to two or more internal reference signals and then, applies the divided signals to appropriate operations for data access. In this case, the semiconductor memory device may have a dividing unit for dividing a frequency of a signal.

FIG. 6A shows a timing diagram for a write operation of the semiconductor memory device in FIG. 5.

In case of the write operation, at first, the operating clock generating unit 120 generates the operating clock TCLKI using the first external clock TCLK. A frequency of the operating clock TCLK is the same as that of the first external clock TCLK. The data clock generating unit 140 generates the data clock DCLKI using the second external clock DCLK. A frequency of the data clock DCLK is the same as that of the second external clock DCLK. The frequency of the second external clock DCLK is higher than that of the first external clock TCLK. In this exemplification, the frequency of the second external clock DCLK is two times as high as that of the first external clock TCLK. Therefore, the frequency of the data clock DCLKI is two times as high as that of the first external clock TCLKI.

Input Data DI[0:m] is inputted through the input/output pad DQ PAD to the data input unit 320A in response to the transition of the data strobe signal DQS. The data strobe signal input unit 420 generates the internal data strobe signal DS_CLK using the data strobe signal DQS. The internal data strobe signal DS_CLK has a transition in response to a rising edge and falling edge of the data strobe signal DQS.

The command decoding unit 221 receives the command signals, e.g., /CS and /RAS and CKE, and generates the internal write command for the write operation. The address input unit 222 generates the internal address and the internal bank address into the core block 240 using an address A<0:n> and a bank address BA<0:i> inputted from an external source.

The data input unit 320A transfers the input data DI[0:m] as the internal data MI to the input prefetch unit 340A in response to transition of the internal data strobe signal DS_CLK. The input prefetch unit 340A aligns the internal data MI into the data 4MI in parallel in response to the internal data strobe signal DS_CLK and outputs the data 4MI in response to the operating clock TCLKI. The core block 240 writes the data 4MI into cells corresponding to the internal address.

As described above, the semiconductor memory device uses the internal data strobe signal DS_CLK derived from the data strobe signal as a reference signal when data are inputted and are aligned into a parallel data. Alternatively, the semiconductor memory device uses the operating clock TCLKI derived from the first external clock TCLK as a reference signal when command signals and addresses are inputted and a write operation is performed.

FIG. 6B shows a timing diagram for a read operation of the semiconductor memory device in FIG. 5.

In case of the read operation, the operating clock generating unit 120 generates the operating clock TCLKI using the first external clock TCLK. A frequency of the operating clock TCLK is the same as that of the first external clock TCLK. The data clock generating unit 140 generates the data clock DCLKI using the second external clock DCLK. A frequency of the data clock DCLK is the same as that of the second external clock DCLK. The frequency of the second external clock DCLK is higher than that of the first external clock TCLK. In this exemplification, the frequency of the second external clock DCLK is two times as high as that of the first external clock TCLK. Therefore, the frequency of the data clock DCLKI is two times as high as that of the first external clock TCLKI.

The command decoding unit 221 receives the command signals, e.g., /CS and /RAS and CKE, and generates the internal read command for the read operation. The address input unit 222 generates the internal address and the internal bank address into the core block 240 using an address A<0:n> and a bank address BA<0:i> inputted from an external source.

The core block 240 outputs data 4MO corresponding to the address A<0:n> and the bank address BA<0:i> into the output prefetch unit 360.

The output prefetch unit 360 receives the data 4MO in parallel in response to the operating clock TCLK and aligns the data 4MO into data MO in series in response to the data clock DCLKI. The data output unit 380 outputs the data MO as the output data DO[0:m] through the input/output pad DQ PAD in response to the data clock DCLKI.

As described above, the semiconductor memory device uses the data clock DCLKI derived from the second external clock TCLK when outputs the output data. Also, the semiconductor memory device uses the operating clock TCLK derived from the first external clock TCLK as a reference signal when command signals and addresses are inputted and a read operation is performed.

In summary, the semiconductor memory device performs the write operation or the read operation using three reference signals, i.e., the data clock DCLKI, the operating clock TCLKI and the internal data strobe signal DS_CLK.

If the frequency of the second external clock DLCK is raised at state of fixing the frequency of the first external clock TLCK, data transmission rate of the semiconductor memory device is raised and the needless power consumption is reduced at the same time. That is, the rate of data input/output is determined to the frequency of the second external clock DLCK and the operation for accessing data is effectively the frequency of the first external clock TCLK having a relatively lower frequency. Therefore, in core area, needless power consumption from the transition of the operating clock can be reduced.

Besides, because the semiconductor memory device performs a read operation or a write operation in response to the first external clock TCLK having a relatively lower frequency, a margin of set-up time and hold time for transferring data in the semiconductor memory device can be increased.

Although it is disclosed about the semiconductor memory described above, it is possible to use various alternatives, modifications and equivalents. For example, those skilled in the art appreciate that the block diagram described in connection with FIGS. 3 and 5 and the frequency differences between reference signals can be employed in the context of any type of logical circuit.

The present application contains subject matter related to Korean patent application No. 2005-90964 and 2005-31956 filed in the Korea Patent Office on Sep. 29, 2005 and Apr. 7, 2006, respectively, the entire contents of which being incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. A method for operating a semiconductor memory device, comprising:
performing a first operation for inputting and outputting data in response to a first clock signal having a first frequency; and
performing a second operation for storing and reading out the data in a core block in response to a second clock signal having a second frequency,
wherein the first frequency is different from the second frequency.

2. A semiconductor memory device, comprising:
an operating unit for storing first data for a write operation or reading out second data for a read operation in response to a first clock signal having a first frequency; and
a data input/output unit for inputting the first data from an external source or outputting the second data to an external destination in response to a second clock signal having a second frequency, wherein the first frequency is different from the second frequency.

3. A semiconductor memory device, comprising:
an operating clock generating unit for generating an operating clock in response to a first external clock having a first frequency;
a data clock generating unit for generating a data clock in response to a second external clock having a second frequency;
a data strobe signal generating unit for generating an internal data strobe signal in response to a data strobe signal for a write operation and generating a data strobe signal for a read operation in response to the data clock;
an operating unit for storing first data for a write operation or reading out second data for a read operation in response to the operating clock; and
a data input/output unit for receiving the first data from an external source in response to the internal data strobe signal and outputting the second data to an external destination in response to the data clock, wherein the first frequency is different from the second frequency.
